(19) United States
(12) Patent Application Publication
(10) Pub. No.: US 2026/0343888 A1
(43) Pub. Date: Oct. 29, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Sang Bum LEE, Gyeonggi-do (KR)

(21) Appl. No.: 19/309,626

(22) Filed: Aug. 26, 2025

(30) Foreign Application Priority Data
Apr. 23, 2025 (KR) 10-2025-0053078

(51) Int. Cl. H10B 43/35; H10B 41/10; H10B 41/27; H10B 41/35; H10B 41/41; H10B 43/10; H10B 43/27; H10B 43/40; H10B 80/00; H10W 90/00

(52) U.S. Cl. CPC H10B 43/35; H10B 41/10; H10B 41/27; H10B 41/35; H10B 41/41; H10B 43/10; H10B 43/27; H10B 43/40; H10B 80/00; H10W 90/00; H10W 90/792

(57) ABSTRACT

A semiconductor device includes: a gate structure including conductive layers and insulating layers, which are alternately stacked; a gate line disposed over the gate structure; a dummy gate line disposed over the gate structure; a first channel structure disposed to penetrate through the gate structure; a second channel structure penetrating through the gate line, and connected to the first channel structure; and contact plugs disposed to penetrate through the dummy gate line and the gate structure, and respectively connected to the conductive layers.

### CROSS-REFERENCE TO RELATED APPLICATION

This application claims priority under 35 U.S.C. § 119 to Korean Patent Application No. 10-2025-0053078 filed on Apr. 23, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate approaches a limit, three-dimensional semiconductor devices for stacking memory cells on a substrate have been proposed. Furthermore, in order to improve the operational reliability of such semiconductor devices, various structures and manufacturing methods have been developed.

### SUMMARY

In an embodiment, a semiconductor device may include: a gate structure including conductive layers and insulating layers, which are alternately stacked; a gate line located over the gate structure; a dummy gate line located over the gate structure; a first channel structure disposed to penetrate through the gate structure; a second channel structure disposed to penetrate through the gate line, and connected to the first channel structure; and contact plugs disposed to penetrate through the dummy gate line and extend into the gate structure, and respectively connected to the conductive layers.

In an embodiment, a semiconductor device may include: a gate structure including stacked word lines; drain select lines disposed over the gate structure, and disposed to extend in a first direction; a dummy drain select line disposed over the gate structure; channel structures disposed to penetrate through the drain select lines, and disposed to extend into the gate structure; and contact plugs disposed to penetrate through the dummy drain select line, and respectively connected to the word lines.

In an embodiment, a method of manufacturing a semiconductor device may include: forming a stack including first material layers and second material layers, which are alternately stacked; forming a first channel structure penetrating through the stack; forming a gate line over the stack; forming a dummy gate line over the stack; forming a channel hole penetrating through the gate line to expose the first channel structure; forming preliminary contact holes penetrating through the dummy gate line; forming a second channel structure in the channel hole to be connected to the first channel structure; extending the preliminary contact holes into the stack to respectively expose the first material layers to form contact holes; and forming contact plugs in the contact holes.

In an embodiment, a method of manufacturing a semiconductor device may include: forming a stack including first material layers and second material layers, which are alternately stacked; forming a first channel hole penetrating through the stack; forming a conductive layer on the stack; patterning the conductive layer to form a drain select line and a dummy drain select line; forming a second channel hole penetrating through the drain select line to be connected to the first channel hole; forming preliminary contact holes penetrating through the dummy drain select line; extending the preliminary contact holes to respectively expose the first material layers to form contact holes; and forming contact plugs in the contact holes.

### BRIEF DESCRIPTION OF THE DRAWINGS

The above and other objects, features and advantages of the present disclosure will be more apparent from the following detailed description taken in conjunction with the accompanying drawings:

FIGS. 1A and 1B are diagrams illustrating the structure of a semiconductor device in accordance with an embodiment of the present disclosure.

FIGS. 2A and 2B are diagrams illustrating the structure of a semiconductor device in accordance with an embodiment of the present disclosure.

FIGS. 3A to 3C are diagrams illustrating the structure of a semiconductor device in accordance with an embodiment of the present disclosure.

FIG. 4 is a diagram illustrating the structure of a semiconductor device in accordance with an embodiment of the present disclosure.

FIG. 5 is a diagram illustrating the structure of a semiconductor device in accordance with an embodiment of the present disclosure.

FIGS. 6A, 7A, 8A, 9A, 10A, 11A, 12A, and 13A and FIGS. 6B, 7B, 8B, 9B, 10B, 11B, 12B, and 13B are diagrams for describing a method of manufacturing a semiconductor device in accordance with an embodiment of the present disclosure.

FIGS. 14A, 15A, 16A, 17A, 18A, and 19A, FIGS. 14B, 15B, 16B, 17B, 18B, and 19B, and FIGS. 18C and 20 are diagrams for describing a method of manufacturing a semiconductor device in accordance with an embodiment of the present disclosure.

FIGS. 21A to 21C are diagrams for describing a method of manufacturing a semiconductor device in accordance with an embodiment of the present disclosure.

FIG. 22 is a configuration diagram of a semiconductor device in accordance with an embodiment of the present disclosure.

FIG. 23 is a configuration diagram of a semiconductor device in accordance with an embodiment of the present disclosure.

### DETAILED DESCRIPTION

Various embodiments are directed to a semiconductor device having a stable structure and improved characteristics and a method of manufacturing the semiconductor device.

Hereinafter, various embodiments of the present disclosure are described with reference to accompanying drawings. Advantages and features of the present disclosure and methods for implementing them will become apparent with reference to embodiments to be described below in detail together with the accompanying drawings. However, this is not intended to limit the present disclosure to specific embodiments.

The present disclosure may be implemented in various different forms without being limited to an embodiment and should be understood as including various modifications, equivalents, and/or alternatives of embodiments of the present disclosure.

Also, in adding reference numerals to components of each drawing, it should be noted that like components are designated by like numerals even though illustrated on other drawings.

In the specification, the singular forms include plural forms unless otherwise mentioned. The terms “comprises” and/or “comprising”, which are used in the specification, specify the presence of components, steps, operations, and/or elements, but do not preclude the presence or addition of one or more other components, steps, operations, and/or elements.

Herein below, by stacking memory cells in three dimensions, the disclosed embodiments provide a capability to improve the degree of integration of a semiconductor device. The disclosed embodiments further provide a semiconductor device having a stable structure and improved reliability.

Hereafter, embodiments in accordance with the technical spirit of the present disclosure will be described with reference to the accompanying drawings.

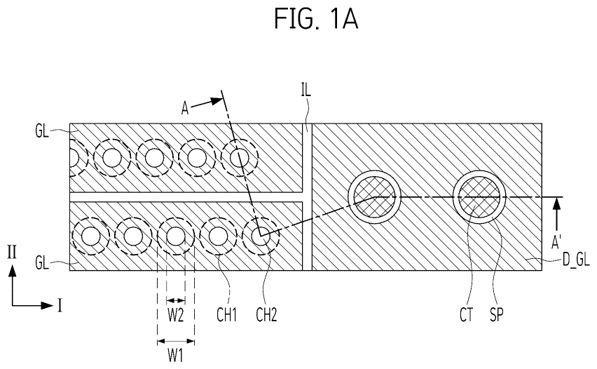

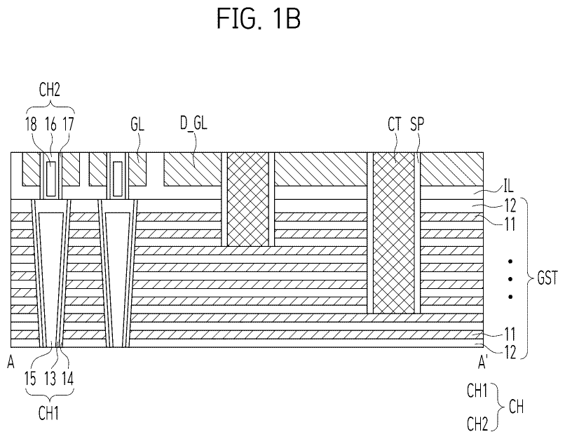

FIGS. 1A and 1B are diagrams illustrating the structure of a semiconductor device in accordance with an embodiment of the present disclosure. FIG. 1A is a layout diagram, and FIG. 1B is a cross-sectional view taken along line A-A′ of FIG. 1A.

Referring to FIG. 1A and FIG. 1B, the semiconductor device may include a gate structure GST, a gate line GL, a dummy gate line D_GL, a channel structure CH, and contact plugs CT. The semiconductor device may further include an interlayer insulating layer IL and an insulating spacer SP.

The gate structure GST may include conductive layers 11 and insulating layers 12, which are alternately stacked. The conductive layers 11 may each include a conductive material such as polysilicon, tungsten (W), or molybdenum (Mo). The insulating layers 12 may each include an insulating material such as oxide, nitride, or air gap. As an example, the conductive layers 11 may be a source select line, word lines, or a drain select line.

The gate line GL may be located over the gate structure GST. The gate line GL may extend in a first direction I. A plurality of gate lines GL may be adjacent to each other in a second direction II intersecting the first direction I. The gate line GL may include a conductive material such as polysilicon, tungsten (W), or molybdenum (Mo). The gate line GL may include a different material from the conductive layers 11. The conductive layers 11 may each include metal such as tungsten (W) or molybdenum (Mo), and the gate line GL may include polysilicon. As an example, the gate line GL may be a drain select line.

The dummy gate line D_GL may be located over the gate structure GST. The gate line GL and the dummy gate line D_GL may be adjacent to each other in the first direction I. In the second direction II, the dummy gate line D_GL may have a greater width than the gate line GL. The dummy gate line D_GL may include a conductive material such as polysilicon, tungsten (W), or molybdenum (Mo). The dummy gate line D_GL may include substantially the same material as the gate line GL. The dummy gate line D_GL may include polysilicon.

The dummy gate line D_GL may be located at substantially the same level as the gate line GL. An upper surface of the dummy gate line D_GL and an upper surface of the gate line GL may be located on the same plane. The interlayer insulating layer IL may be located between the dummy gate line D_GL and the gate line GL, and the dummy gate line D_GL may be electrically separated from the gate line GL. The dummy gate line D_GL may have an electrically floated state.

The channel structure CH may include a first channel structure CH1 and a second channel structure CH2. The first channel structure CH1 may penetrate through the gate structure GST. The first channel structure CH1 may include a first channel layer 13, a memory layer 14 surrounding the first channel layer 13, and a first insulating core 15 located in the first channel layer 13. The gate line GL may be located on the first channel structure CH1. The memory layer 14 may include at least one of a tunneling layer, a data storage layer, and a blocking layer. The data storage layer may include a floating gate, polysilicon, a charge trap material, nitride, a variable resistance material, or the like.

The second channel structure CH2 may penetrate through the gate line GL, and may be connected to the first channel structure CH1. The second channel structure CH2 may include a second channel layer 16 connected to the first channel layer 13, a gate insulating layer 17 surrounding the second channel layer 16, and a second insulating core 18 located in the second channel layer 16. In a plane defined by the first direction I and the second direction II, the first channel structure CH1 and the second channel structure CH2 may have the same width or different widths. As an example, the second channel structure CH2 may have a second width W2, and the first channel structure CH1 may have a first width W1 greater than the second width W2.

The contact plugs CT may penetrate through the dummy gate line D_GL and extend through the gate structure GST. The contact plugs CT may penetrate through the dummy gate line D_GL, and may extend into the gate structure GST at different depths. The contact plugs CT may be connected to (for example, each of) the conductive layers 11, respectively. The insulating spacers SP may surround sidewalls of the contact plugs CT, respectively.

According to the structure described over, the gate line GL and the dummy gate line D_GL may be located over the gate structure GST. The gate line GL may be the drain select line, and drain select transistors may be located in regions where the second channel structures CH2 and the gate line GL intersect each other. The drain select lines are separated from each other without cutting the drain select transistors, and the disclosed embodiments may therefore improve leakage current characteristics of the drain select transistors.

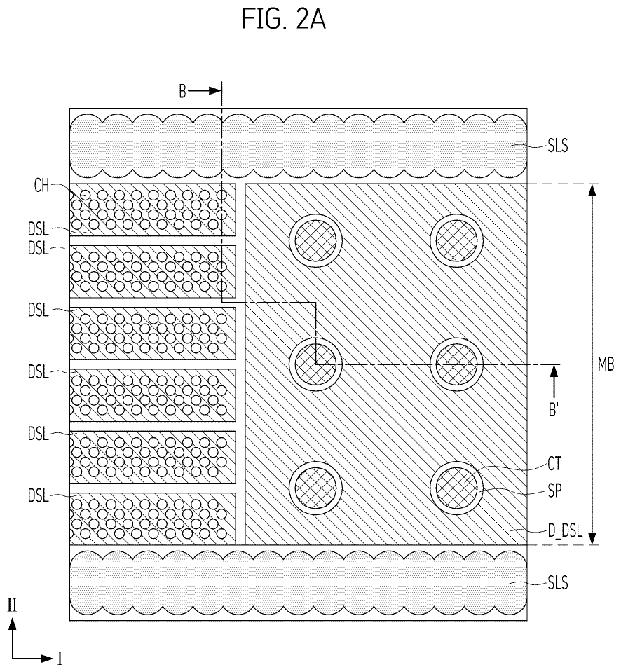

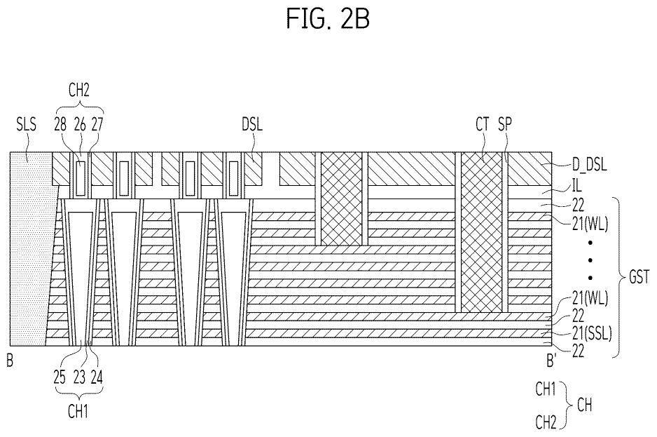

FIGS. 2A and 2B are diagrams illustrating the structure of a semiconductor device in accordance with an embodiment of the present disclosure. FIG. 2A is a layout diagram, and FIG. 2B is a cross-sectional view taken along line B-B′ of FIG. 2A. Hereinafter, content overlapping with previously described content may be omitted.

Referring to FIGS. 2A and 2B, the semiconductor device may include a gate structure GST, drain select lines DSL, a dummy drain select line D_DSL, channel structures CH, and contact plugs CT. The semiconductor device may further include an interlayer insulating layer IL, an insulating spacer SP, and slit structures SLS.

The gate structure GST may include conductive layers 21 and insulating layers 22, which are alternately stacked. As an example, the conductive layers 21 may include at least one source select line SSL and word lines WL stacked over at least one source select line SSL. The conductive layers 21 may each include metal such as tungsten (W) or molybdenum (Mo).

The slit structures SLS may extend in the first direction I. The gate structure GST may be located between a pair of slit structures SLS adjacent to each other in the second direction II. The slit structures SLS may each include an insulating material, a semiconductor material, a conductive material, or the like.

The drain select line DSL may be located over the gate structure GST. The drain select line DSL may extend in the first direction I. A plurality of drain select lines DSL may be adjacent to each other in the second direction II intersecting the first direction I. As an example, the drain select line DSL may include polysilicon.

The dummy drain select line D_DSL may be located over the gate structure GST. The drain select line DSL and the dummy drain select line D_DSL may be adjacent to each other in the first direction I. In the second direction II, the dummy drain select line D_DSL may have a greater width than the drain select line DSL. The dummy drain select line D_DSL may be located at substantially the same level as the drain select line DSL. The dummy drain select line D_DSL may include polysilicon.

The channel structures CH may penetrate through the drain select line DSL, and may extend into the gate structure GST. Each of the channel structures CH may include a first channel structure CH1 and a second channel structure CH2. The first channel structure CH1 may penetrate through the gate structure GST. The first channel structure CH1 may include a first channel layer 23, a memory layer 24 surrounding the first channel layer 23, and a first insulating core 25 located in the first channel layer 23. The drain select line DSL may be located over the first channel structure CH1.

The second channel structure CH2 may penetrate through the drain select line DSL, and may be connected to the first channel structure CH1. The second channel structure CH2 may include a second channel layer 26 connected to the first channel layer 23, a gate insulating layer 27 surrounding the second channel layer 26, and a second insulating core 28 located in the second channel layer 26.

A source select transistor may be located in a region where the first channel structure CH1 and the source select line SSL intersect each other, and a memory cell may be located in a region where the first channel structure CH1 and the word line WL intersect each other. A drain select transistor may be located in a region where the second channel structure CH2 and the drain select line DSL intersect each other. At least one source select transistor, a plurality of memory cells, and at least one drain select transistor that are stacked along the channel structure CH may constitute one memory string. The source select transistor and the memory cell belonging to one memory string may share the first channel layer 23 with each other, and the drain select transistor may include the second channel layer 26.

The contact plugs CT may penetrate through the dummy drain select line D_DSL and extend through the gate structure GST. The contact plugs CT may penetrate through the dummy drain select line D_DSL, and may extend into the gate structure GST at different depths. The contact plugs CT may be connected to the conductive layers 21, respectively. The insulating spacers SP may surround sidewalls of the contact plugs CT, respectively.

For reference, supports (not illustrated) may be located around the contact plugs CT. The supports may penetrate through the dummy drain select line D_DSL and the gate structure GST. The supports may each include an insulating material, a semiconductor material, or a conductive material. As an example, the supports may be dummy channel structures, and may each include a dummy channel layer, a dummy memory layer, and a dummy insulating core.

In accordance with the structure described above, the drain select line DSL and the dummy drain select line D_DSL may be located over the gate structure GST. The drain select lines DSL and the dummy drain select line D_DSL located between the pair of slit structures SLS may belong to the same memory block MB. As an example, channel structures CH arranged in the first direction I may constitute one row, and the memory block MB may include twenty four rows. Four rows may share one drain select line DSL with each other, and the memory block MB may include six drain select lines DSL. The dummy drain select line D_DSL may have a width corresponding to the six drain select lines DSL. The memory block MB may be a unit of an erase operation.

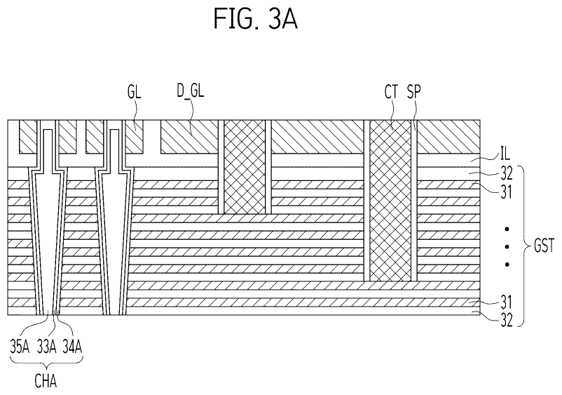

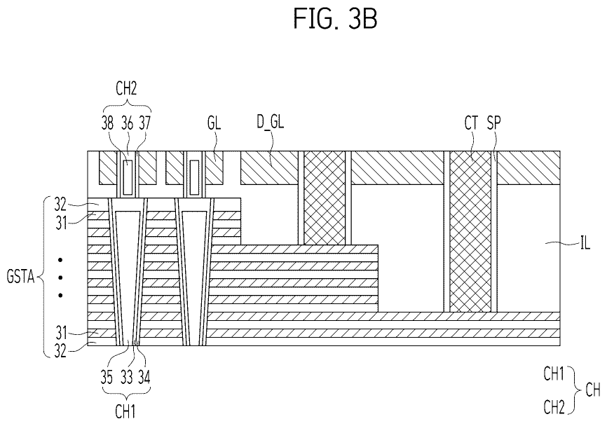

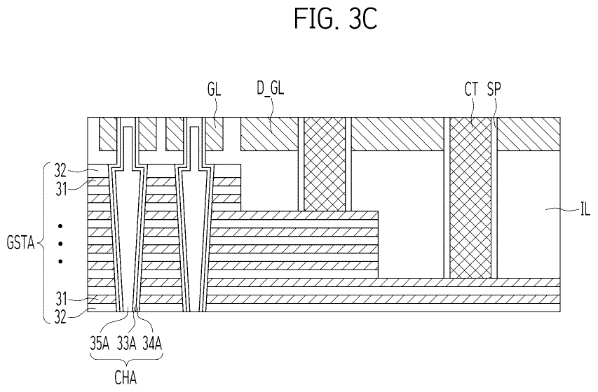

FIGS. 3A to 3C are diagrams illustrating the structure of a semiconductor device in accordance with an embodiment of the present disclosure. Hereinafter, content overlapping with previously described content may be omitted.

Referring to FIG. 3A, the semiconductor device may include a gate structure GST, gate lines GL, a dummy gate line D_GL, a channel structure CHA, and contact plugs CT. The semiconductor device may further include an interlayer insulating layer IL and insulating spacers SP. The gate structure GST may include conductive layers 31 and insulating layers 32, which are alternately stacked.

The channel structure CHA may penetrate through the gate line GL and the gate structure GST. The channel structure CHA may include a channel layer 33A, a memory layer 34A, and an insulating core 35A. The channel layer 33A may penetrate through the gate line GL, and may extend into the gate structure GST. The memory layer 34A may surround sidewalls of the channel layer 33A. The insulating core 35A may be located in the channel layer 33A.

At least one source select transistor, memory cells, and at least one drain select transistor that are stacked along the channel structure CHA may share the channel layer 33A with each other. A source select line and a word line may each include metal, and a drain select line may include polysilicon.

Referring to FIG. 3B, the semiconductor device may include a gate structure GSTA, gate lines GL, a dummy gate line D_GL, a channel structure CH, and contact plugs CT. The semiconductor device may further include an interlayer insulating layer IL and insulating spacers SP.

The gate structure GSTA may include conductive layers 31 and insulating layers 32, which are alternately stacked, and may include a staircase structure. Pad portions of the conductive layers 31 may be defined by the staircase structure. A portion of the conductive layer 31 that is not covered by an upper conductive layer may be the pad portion. The contact plugs CT may be connected to the pad portions of the conductive layers 31, respectively. The dummy gate line D_GL may be located over the staircase structure.

Referring to FIG. 3C, the semiconductor device may include a gate structure GSTA, gate lines GL, a dummy gate line D_GL, a channel structure CHA, and contact plugs CT. The semiconductor device may further include an interlayer insulating layer IL and insulating spacers SP. The gate structure GSTA may include a staircase structure. The channel structure CHA may include a channel layer 33A penetrating through the gate line GL and extending into the gate structure GSTA.

In accordance with the structure described above, the gate lines GL and the dummy gate line D_GL may be located over the gate structure GST or GSTA, and the gate lines GL may be drain select lines. The drain select lines are separated from each other without cutting the drain select transistors, and the disclosed embodiments therefore provide a capability to improve leakage current characteristics of the drain select transistors.

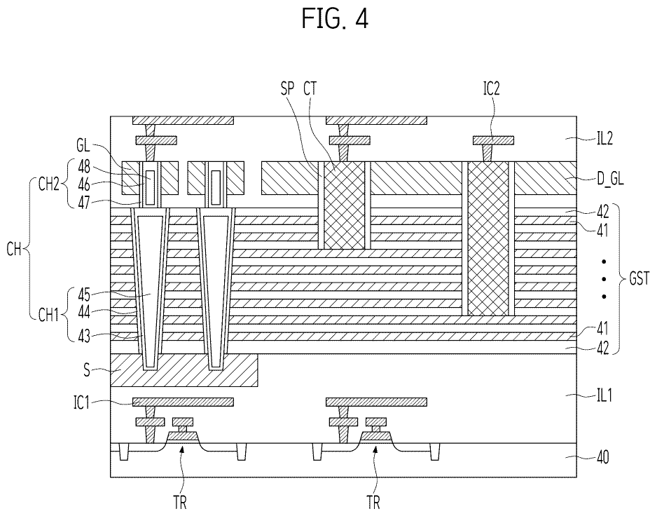

FIG. 4 is a diagram illustrating the structure of a semiconductor device in accordance with an embodiment of the present disclosure. Hereinafter, content overlapping with previously described content may be omitted.

Referring to FIG. 4, the semiconductor device may include a substrate 40, a transistor TR, a first interconnection structure IC1, a first interlayer insulating layer IL1, a source structure S, a gate structure GST, a gate line GL, a dummy gate line D_GL, a channel structure CH, a second interconnection structure IC2, and a second interlayer insulating layer IL2. A peripheral circuit may be located under a memory cell array.

The transistor TR may be located on the substrate 40. The transistor TR may belong to the peripheral circuit. As an example, the peripheral circuit may include a row decoder, a page buffer, an input/output circuit, a logic circuit, and the like. The first interconnection structure IC1 may be formed in the first interlayer insulating layer IL1, and may be electrically connected to the peripheral circuit. The first interconnection structure IC1 may include a via, a wiring line, and the like.

The source structure S may be located over the peripheral circuit. The source structure S may have a form patterned in a string unit or a memory block unit. The gate structure GST may be located on the source structure S. The gate structure GST may include conductive layers 41 and insulating layers 42, which are alternately stacked. The gate lines GL and the dummy gate line D_GL may be located over the gate structure GST. The gate lines GL and the dummy gate line D_GL may be located at substantially the same level, and may include substantially the same material. The gate lines GL may be drain select lines, and the drain select lines may be separated from each other without cutting a drain select transistor.

The channel structures CH may penetrate through the gate lines GL and the gate structure GST, and may be connected to the source structure S. The channel structure CH may include a first channel structure CH1 and a second channel structure CH2. The first channel structure CH1 may include a first channel layer 43, a memory layer 44, and a first insulating core 45. The second channel structure CH2 may include a second channel layer 46, a gate insulating layer 47, and a second insulating core 48.

Contact plugs CT may penetrate through the dummy gate line D_GL, and may extend into the gate structure GST. The contact plugs CT may extend at different depths, and may be connected to the conductive layers 41, respectively.

The second interconnection structure IC2 may be located in the second interlayer insulating layer IL2, and may be connected to the channel structure CH, the contact plug CT, or the like. The second interconnection structure IC2 may include a via, a wiring line, and the like.

In accordance with the structure described above, by locating the peripheral circuit under the memory cell array, the disclosed embodiments increase the degree of integration of the semiconductor device. In addition, the gate lines GL and the dummy gate line D_GL may be located over the gate structure GST, and the gate lines GL may be the drain select lines. The drain select lines are separated from each other without cutting the drain select transistors, and the disclosed embodiments therefore prove a capability to improve leakage current characteristics of the drain select transistors.

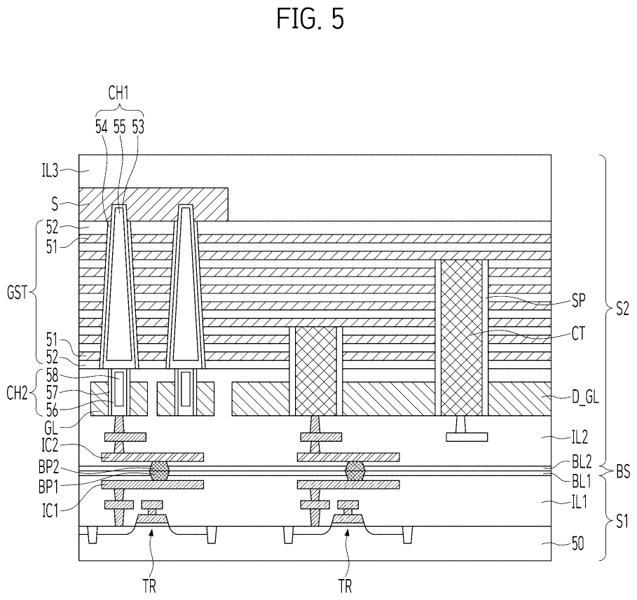

FIG. 5 is a diagram illustrating the structure of a semiconductor device in accordance with an embodiment of the present disclosure. Hereinafter, content overlapping with previously described content may be omitted.

Referring to FIG. 5, the semiconductor device may include a first semiconductor structure S1, a second semiconductor structure S2, and a bonding structure BS. The first semiconductor structure S1 may include a peripheral circuit, and the second semiconductor structure S2 may include a memory cell array.

The first semiconductor structure S1 may include a substrate 50, a transistor TR, a first interlayer insulating layer IL1, and a first interconnection structure IC1. The transistor TR may belong to the peripheral circuit. The first interconnection structure IC1 may be located in the first interlayer insulating layer IL1, and may include a via, a wiring line, and the like. The first interconnection structure IC1 may be electrically connected to the peripheral circuit.

The second semiconductor structure S2 may include a source structure S, a gate structure GST, a gate line GL, a dummy gate line D_GL, a channel structure CH, a second interlayer insulating layer IL2, and a second interconnection structure IC2.

The source structure S may be located over the gate structure GST. The gate structure GST may include conductive layers 51 and insulating layers 52, which are alternately stacked. The gate line GL and the dummy gate line D_GL may be located under the gate structure GST. The gate line GL and the dummy gate line D_GL may be located at substantially the same level, and may include substantially the same material. The gate lines GL may be drain select lines, and the drain select lines may be separated from each other without cutting a drain select transistor.

The channel structures CH may penetrate through the gate lines GL and the gate structure GST, and may be connected to the source structure S. The channel structure CH may include a first channel structure CH1 and a second channel structure CH2. The first channel structure CH1 may include a first channel layer 53, a memory layer 54, and a first insulating core 55. The second channel structure CH2 may include a second channel layer 56, a gate insulating layer 57, and a second insulating core 58.

Contact plugs CT may penetrate through the dummy gate line D_GL, and may extend into the gate structure GST. The contact plugs CT may extend at different depths, and may be connected to the conductive layers 51, respectively.

The bonding structure BS may be located between the first semiconductor structure S1 and the second semiconductor structure S2. The first semiconductor structure S1 and the second semiconductor structure S2 may be manufactured separately, and may be electrically connected to each other by the bonding structure BS. The memory cell array including the gate lines GL and the peripheral circuit including the transistor TR may be electrically connected to each other through the bonding structure BS.

The bonding structure BS may include a first bonding layer BL1, a second bonding layer BL2, a first bonding pad BP1, and a second bonding pad BP2. The first bonding layer BL1 and the second bonding layer BL2 may be in contact with each other, and the first bonding pad BP1 and the second bonding pad BP2 may be in contact with each other. The first bonding layer BL1 and the second bonding layer BL2 may each include silicon carbonitride (SiCN), tetra ethyl ortho silicate (TEOS), or the like. The first bonding pad BP1 may be electrically connected to the first interconnection structure IC1, and the second bonding pad BP2 may be electrically connected to the second interconnection structure IC2. The memory cell array and the peripheral circuit may be electrically connected to each other through the first bonding pad BP1 and the second bonding pad BP2.

In accordance with the structure described above, the first semiconductor structure S1 and the second semiconductor structure S2 are bonded to each other in a vertical direction, and the disclosed embodiments therefore provide a capability to increase the degree of integration of the semiconductor device. In addition, the gate line GL and the dummy gate line D_GL may be located under the gate structure GST, and the gate line GL may be the drain select line. The drain select lines are separated from each other without cutting the drain select transistors, and the disclosed embodiments therefore provide a capability to improve leakage current characteristics of the drain select transistors.

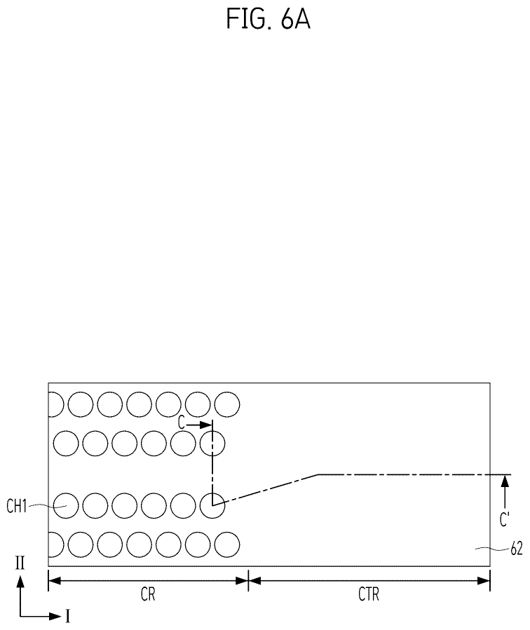

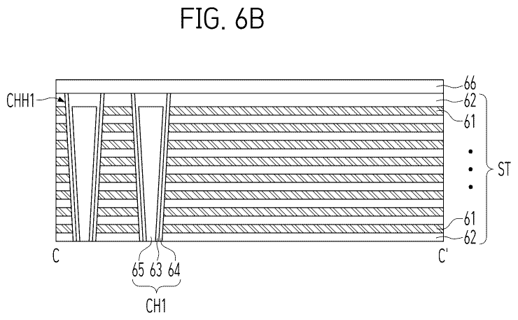

FIGS. 6A, 7A, 8A, 9A, 10A, 11A, 12A, and 13A and FIGS. 6B, 7B, 8B, 9B, 10B, 11B, 12B, and 13B are diagrams for describing a method of manufacturing a semiconductor device in accordance with an embodiment of the present disclosure. FIGS. 6A, 7A, 8A, 9A, 10A, 11A, 12A, and 13A are layout diagrams, and FIGS. 6B, 7B, 8B, 9B, 10B, 11B, 12B, and 13B are cross-sectional views taken along lines C-C′ of FIGS. 6A, 7A, 8A, 9A, 10A, 11A, 12A, and 13A, respectively. Hereinafter, content overlapping with previously described content may be omitted.

Referring to FIGS. 6A and 6B, a stack ST including first material layers 61 and second material layers 62, which are alternately stacked, may be formed. The first material layers 61 may be used to form gate lines, and the second material layers 62 may be used to form insulating layers for insulating the stacked gate lines from each other. The first material layers 61 may each include a material having a high etching selectivity with respect to the second material layers 62. As an example, the first material layers 61 may each include a sacrificial material such as nitride, and the second material layers 62 may each include an insulating material such as oxide. The first material layers 61 may each include a conductive material such as polysilicon or metal, and the second material layers 62 may each include an insulating material such as oxide.

The stack ST may include a cell region CR and a contact region CTR. The cell region CR may be a region where memory cells are stacked. The contact region CTR may be a region where interconnection structures for driving the stacked gate lines, respectively, are located. The cell region CR and the contact region CTR may be adjacent to each other in the first direction I.

Subsequently, a first channel hole CHH1 may be formed in the cell region CR of the stack ST. The first channel hole CHH1 may extend in a vertical direction, and may have a shape such as a circular shape, an elliptical shape, or a polygonal shape in a plan view. Subsequently, a first channel structure CH1 may be formed in the first channel hole CHH1. The first channel structure CH1 may include a first channel layer 63, a memory layer 64, and a first insulating core 65. Subsequently, an insulating layer 66 may be formed on the stack ST.

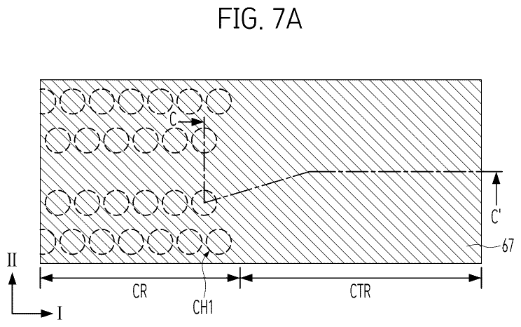

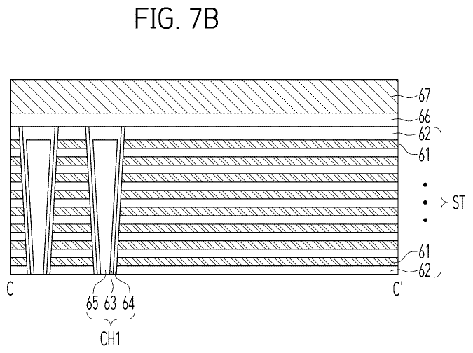

Referring to FIGS. 7A and 7B, a conductive layer 67 may be formed over the stack ST. As an example, the conductive layer 67 may include a conductive material such as polysilicon. The conductive layer 67 may be formed to cover the cell region CR and the contact region CTR.

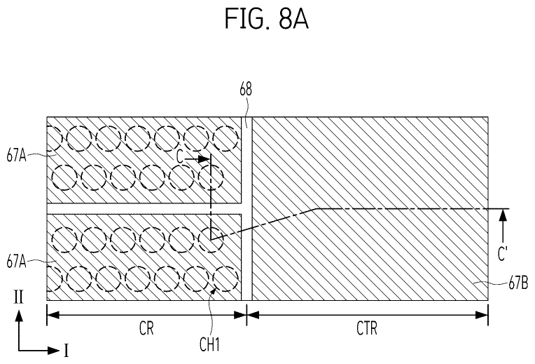

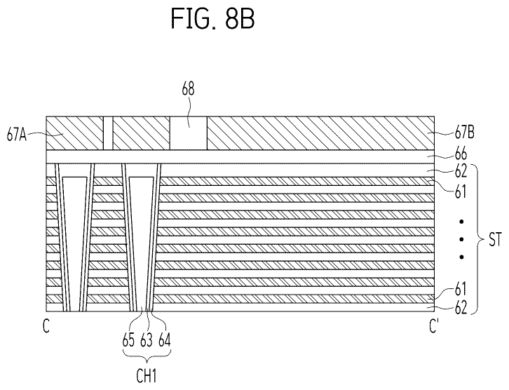

Referring to FIGS. 8A and 8B, a gate line 67A and a dummy gate line 67B may be formed by patterning the conductive layer 67. As an example, a trench may be formed by etching the conductive layer 67, and an insulating material may be formed to fill the trench. Subsequently, an insulating layer 68 may be formed by planarizing the insulating material until the gate line 67A and the dummy gate line 67B are exposed. Through this, the gate lines 67A and the dummy gate line 67B located at substantially the same level and insulated from each other may be formed. The gate line 67A and the dummy gate line 67B are used as stop layers when the insulating material is planarized, and the disclosed embodiments may therefore reduce the occurrence of dishing (by serving as a polishing stop layer that prevents over-polishing of the insulating material).

The gate line 67A may be located in the cell region CR. The gate line 67A may extend in the first direction I, and a plurality of gate lines 67A may be adjacent to each other in the second direction II. The dummy gate line 67B may be located in the contact region CTR. The dummy gate line 67B may be adjacent to the gate line 67A in the first direction I.

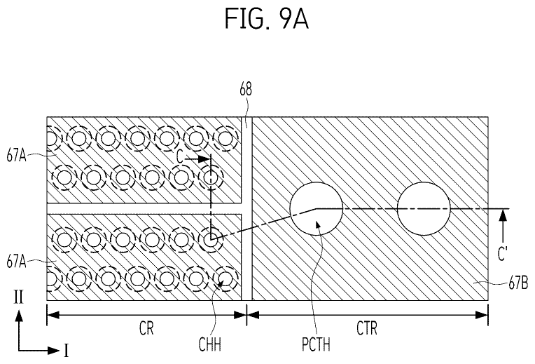

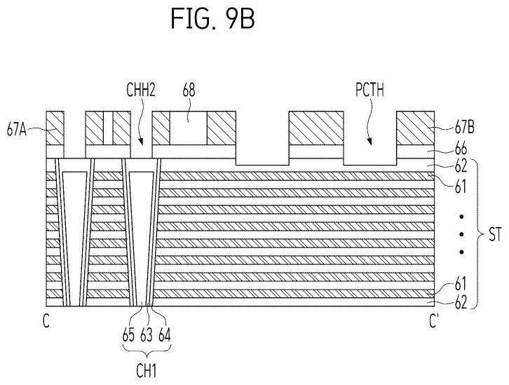

Referring to FIGS. 9A and 9B, a second channel hole CHH2 penetrating through the gate line 67A and exposing the first channel structure CH1 may be formed. The second channel hole CHH2 may penetrate through the gate line 67A and the insulating layer 66. Preliminary contact holes PCTH penetrating through the dummy gate line 67B and exposing the stack ST may be formed. The preliminary contact holes PCTH may penetrate through the dummy gate line 67B and the insulating layer 66. When the second channel hole CHH2 is formed, the preliminary contact holes PCTH may be formed. The preliminary contact holes PCTH may each have a greater width than the second channel hole CHH2.

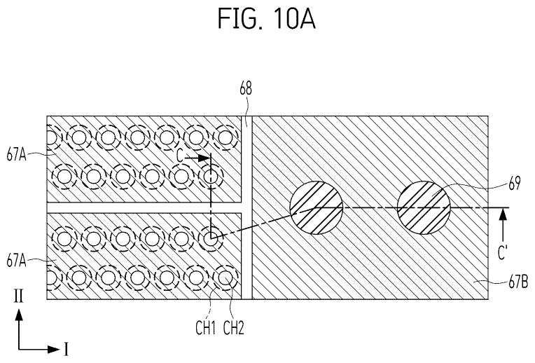

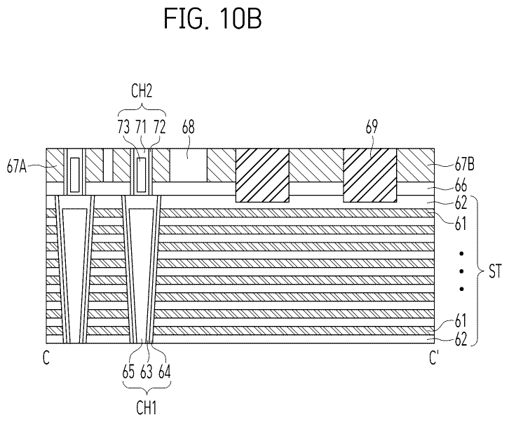

Referring to FIGS. 10A and 10B, a second channel structure CH2 may be formed in the second channel hole CHH2. The second channel structure CH2 may include a second channel layer 71, a gate insulating layer 72 surrounding the second channel layer 71, and a second insulating core 73 located in the second channel layer 71.

First, sacrificial layers 69 may be formed in the second channel hole CHH2 and the preliminary contact holes PCTH. The sacrificial layer 69 may include a material having a high etching selectivity with respect to the gate line 67A, and may include a carbon layer. Subsequently, the second channel hole CHH2 may be reopened by removing the sacrificial layer 69 formed in the second channel hole CHH2, and the second channel structure CH2 may be formed in the second channel hole CHH2. Subsequently, the sacrificial layer 69 may be removed.

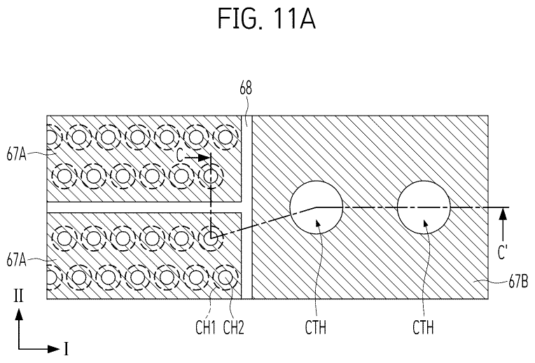

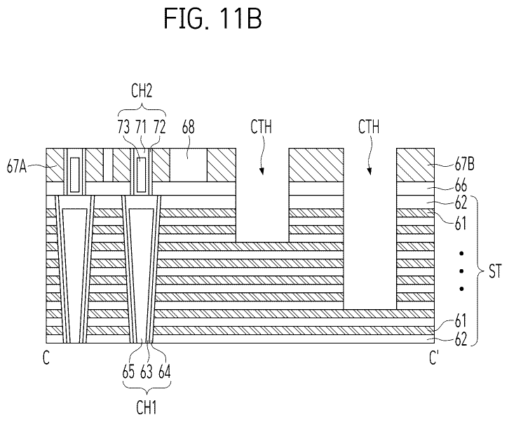

Referring to FIGS. 11A and 11B, the preliminary contact holes PCTH may extend into the stack ST so as to expose the first material layers 61, respectively. Through this, contact holes CTH having different depths may be formed. When the stack ST is etched, the dummy gate line 67B may be used as a hard mask.

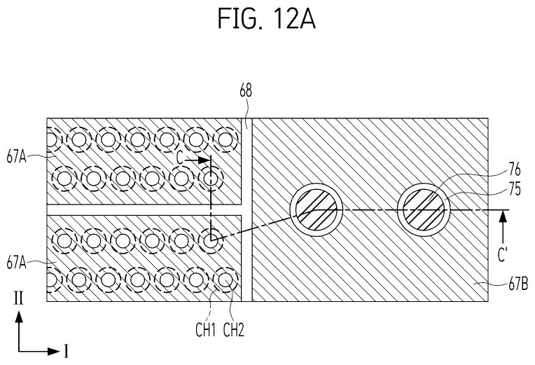

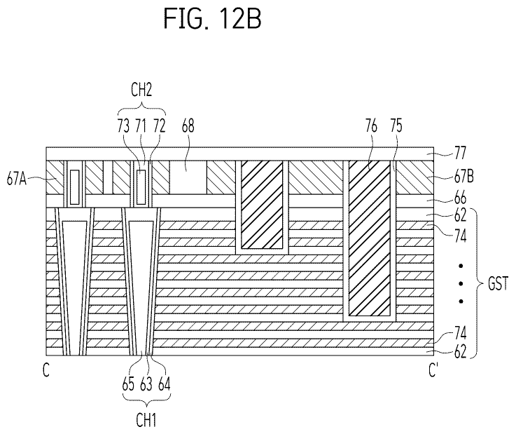

Referring to FIGS. 12A and 12B, insulating layers 75 and sacrificial layers 76 may be formed in the contact holes CTH. The sacrificial layers 76 may include carbon layers or polysilicon layers. Subsequently, an insulating layer 77 may be formed on the gate lines 67A and the dummy gate line 67B. Subsequently, the first material layers 61 may be replaced with third material layers 74. The third material layers 74 may each include metal such as tungsten (W) or molybdenum (Mo). Through this, a gate structure GST including the second material layers 62 and the third material layers 74, which are alternately stacked, may be formed. For reference, when the first material layers 61 each include a conductive material such as polysilicon, a process of replacing the first material layers 61 with third material layers 74 may be omitted, and the stack ST may be used as the gate structure GST.

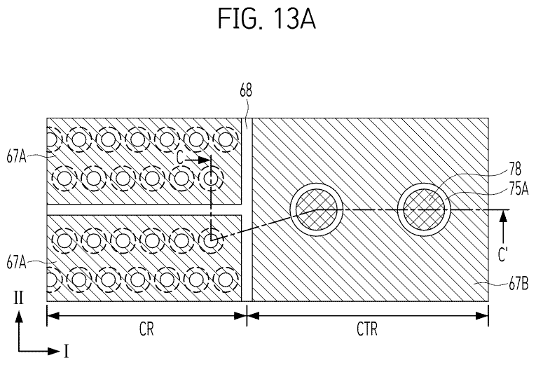

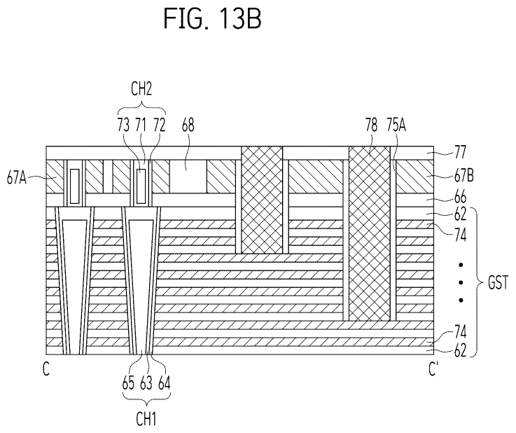

Referring to FIGS. 13A and 13B, holes penetrating through the insulating layer 77 and exposing the sacrificial layer 76 may be formed. Subsequently, the sacrificial layers 76 may be removed, and insulating spacers 75A may be formed by etching the insulating layers 75. Subsequently, contact plugs 78 may be formed in the contact holes CTH.

According to the method described over, the gate line 67A and the dummy gate line 67B may be formed over the stack ST. The insulating material is planarized using the gate line 67A and the dummy gate line 67B as the stop layers, and it is thus possible to reduce the occurrence of the dishing. When the contact holes CTH are formed, the dummy gate line 67B may be used as the hard mask.

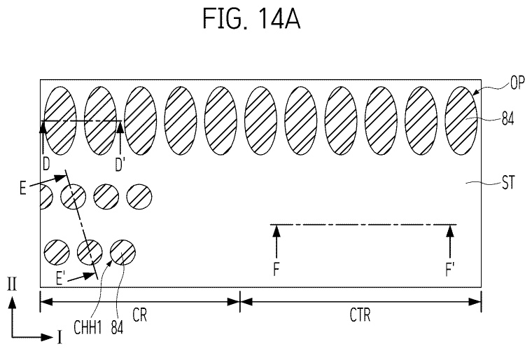

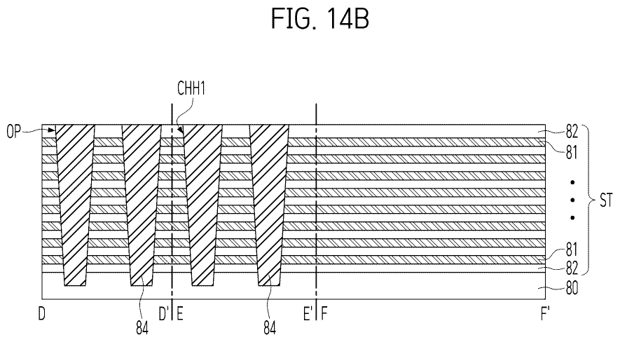

FIGS. 14A, 15A, 16A, 17A, 18A, and 19A, FIGS. 14B, 15B, 16B, 17B, 18B, and 19B, and FIGS. 18C and 20 are diagrams for describing a method of manufacturing a semiconductor device in accordance with an embodiment of the present disclosure. FIGS. 14A, 15A, 16A, 17A, 18A, and 19A are layout diagrams, and FIGS. 14B, 15B, 16B, 17B, 18B, and 19B are cross-sectional views taken along lines C-C′ of FIGS. 14A, 15A, 16A, 17A, 18A, and 19A, respectively. Hereinafter, content overlapping with previously described content may be omitted.

Referring to FIGS. 14A and 14B, a stack ST including first material layers 81 and second material layers 82, which are alternately stacked, may be formed. Subsequently, openings OP and first channel holes CHH1 may be formed in the stack ST. When the first channel holes CHH1 are formed, the openings OP may be formed. The first channel holes CHH1 may be located in a cell region CR, and the openings OP may be located in the cell region CR and a contact region CTR. The openings OP may be arranged along the first direction I. In the second direction II, the opening OP may have a greater width than the first channel hole CHH1.

Subsequently, first sacrificial layers 84 may be formed in the openings OP and the first channel holes CHH1. The first sacrificial layers 84 may each include a material having a high etching selectivity with respect to the first and second material layers 81 and 82. As an example, the first sacrificial layers 84 may each include a polysilicon layer or a carbon layer.

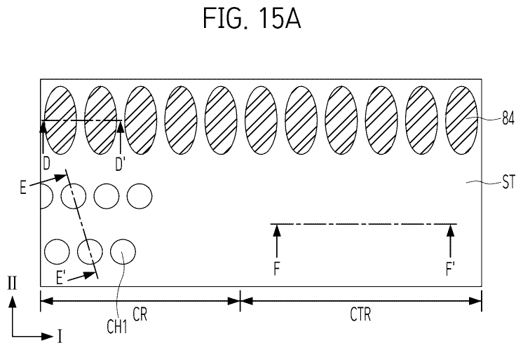

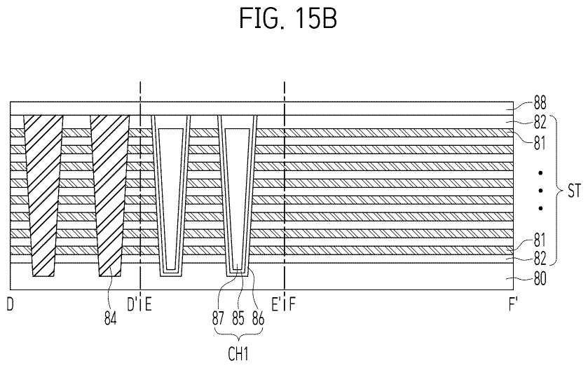

Referring to FIGS. 15A and 15B, the first sacrificial layers 84 formed in the first channel holes CHH1 may be replaced with first channel structures CH1. Each of the first channel structures CH1 may include a first channel layer 85, a memory layer 86, and a first insulating core 87. Subsequently, an insulating layer 88 may be formed on the stack ST.

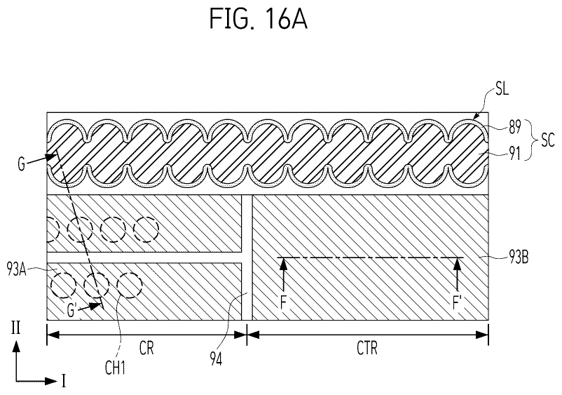

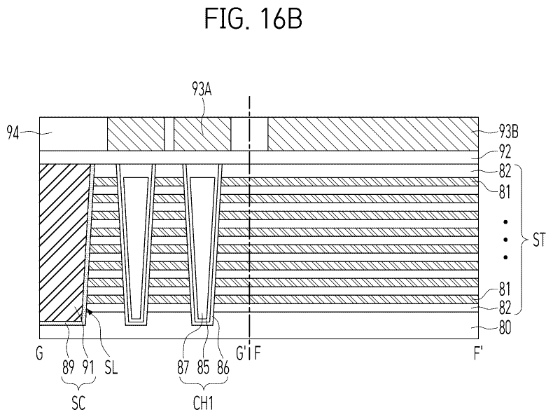

Referring to FIGS. 16A and 16B, the first sacrificial layers 84 may be exposed by etching the insulating layer 88, and the openings OP may be reopened by removing the first sacrificial layers 84. Subsequently, a slit SL may be formed by etching the stack ST through the openings OP. As an example, the slit SL may be formed by selectively etching the first material layers 81 and then selectively etching the second material layers 82 to connect the openings OP to each other.

Subsequently, a sacrificial structure SC may be formed in the slit SL. The sacrificial structure SC may include an insulating layer 89 and a second sacrificial layer 91. The insulating layer 89 may include oxide. The second sacrificial layer 91 may include a material having a high etching selectivity with respect to the first and second material layers 81 and 82. The second sacrificial layer 91 may include a polysilicon layer or a carbon layer.

Subsequently, an insulating layer 92 may be formed over the stack ST, and a conductive layer may be formed over the insulating layer 92. Subsequently, gate lines 93A and a dummy gate line 93B may be formed by patterning the conductive layer. The gate lines 93A may be located in the cell region CR, and the dummy gate line 93B may be located in the contact region CTR. Subsequently, an insulating layer 94 may be formed between the gate lines 93A and the dummy gate line 93B.

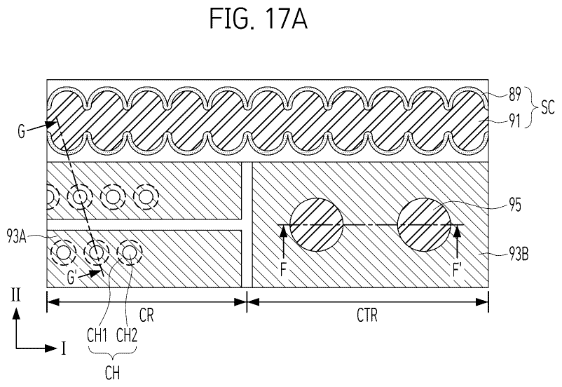

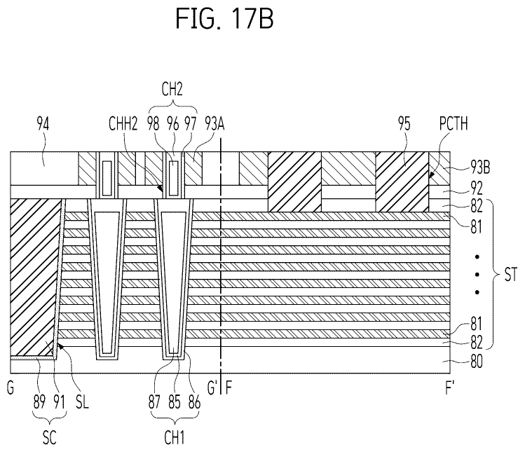

Referring to FIGS. 17A and 17B, second channel holes CHH2 penetrating through the gate lines 93A and exposing the first channel structures CH1 and preliminary contact holes PCTH penetrating through the dummy gate line 93B and exposing the stack ST may be formed. Subsequently, third sacrificial layers 95 may be formed in the second channel holes CHH2 and the preliminary contact holes PCTH. Subsequently, the third sacrificial layers 95 formed in the second channel holes CHH2 may be replaced with second channel structures CH2. The second channel structure CH2 may include a second channel layer 96, a gate insulating layer 97 surrounding the second channel layer 96, and a second insulating core 98 located in the second channel layer 96.

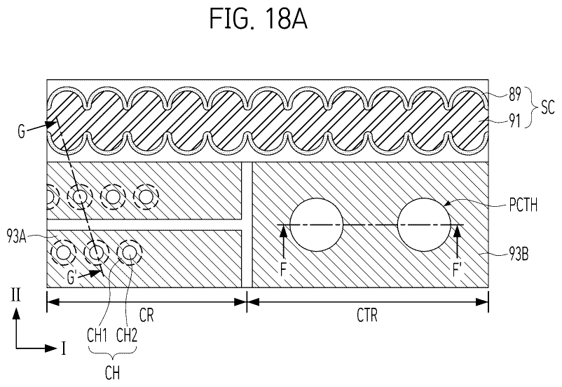

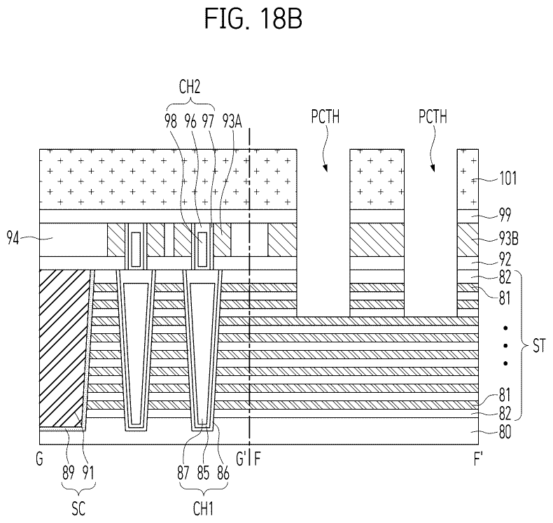

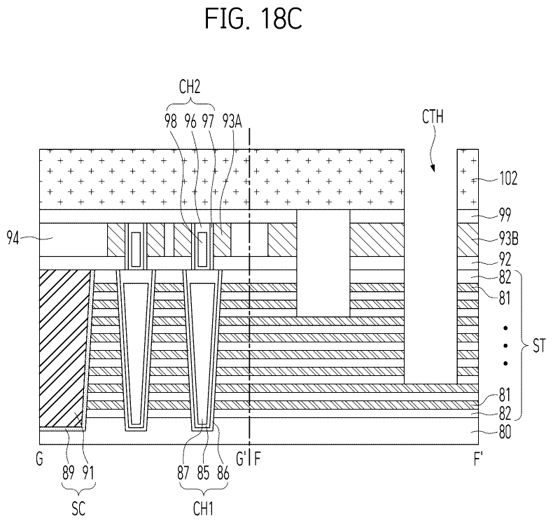

Referring to FIGS. 18A to 18C, an insulating layer 99 may be formed on the gate lines 93A and the dummy gate line 93B. Subsequently, the third sacrificial layers 95 may be exposed by etching the insulating layer 99, and the preliminary contact holes PCTH may be reopened by removing the third sacrificial layers 95. Subsequently, contact holes CTH having different depths may be formed by extending the preliminary contact holes PCTH into the stack ST.

First, referring to FIG. 18B, a first mask pattern 101 may be formed over the dummy gate line 93B where the preliminary contact holes PCTH are reopened. The first mask pattern 101 may expose some of the preliminary contact holes PCTH, and may cover the remaining preliminary contact holes PCTH, the slit SL, and the second channel structures CH2. The first mask pattern 101 may include a carbon layer. Subsequently, the preliminary contact holes PCTH may extend into the stack ST by etching the stack ST using the first mask pattern 101 as an etching barrier. When the stack ST is etched, the dummy gate line 93B may be used as a hard mask together with the first mask pattern 101. Subsequently, the first mask pattern 101 may be removed.

Subsequently, referring to FIG. 18C, a second mask pattern 102 may be formed over the dummy gate line 93B. The second mask pattern 102 may expose some of the preliminary contact holes PCTH, and may cover the remaining preliminary contact holes PCTH, the slit SL, and the second channel structures CH2. The second mask pattern 102 may include a carbon layer. Subsequently, the preliminary contact holes PCTH may extend into the stack ST by etching the stack ST using the second mask pattern 102 as an etching barrier. When the stack ST is etched, the dummy gate line 93B may be used as a hard mask together with the second mask pattern 102. Subsequently, the second mask pattern 102 may be removed.

Through this, the preliminary contact holes PCTH may extend at different depths, and the contact holes CTH exposing the first material layers 81, respectively, may be formed. Dishing is improved by the dummy gate line 93B, and the disclosed embodiments may thereby increase a focus margin when forming the first and second mask patterns 101 and 102. The number of mask patterns used to form the contact holes CTH may be changed depending on the number of the contact holes CTH.

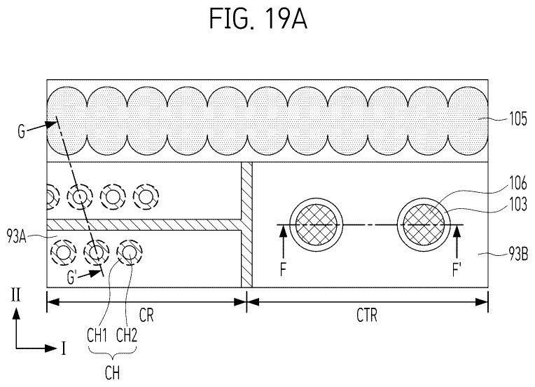

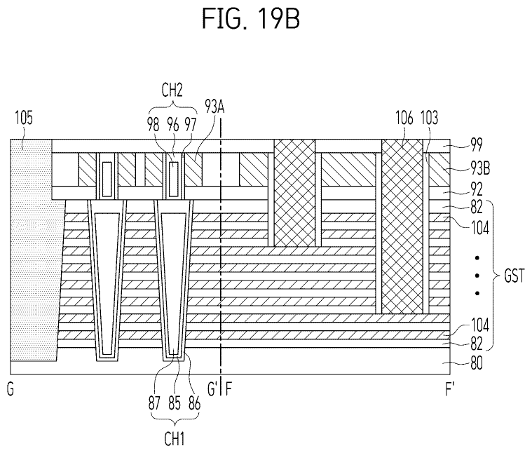

Referring to FIGS. 19A and 19B, insulating layers and sacrificial layers may be formed in the contact holes CTH, and the slit SL may be reopened by removing the sacrificial structure SC. Subsequently, the first material layers 81 may be replaced with third material layers 104 through the slit SL. The third material layers 104 may include at least one source select line and word lines stacked over at least one source select line. Through this, a gate structure GST including the second material layers 82 and the third material layers 104, which are alternately stacked, may be formed. Subsequently, a slit structure 105 may be formed in the slit SL. The slit structure 105 may include an insulating material, a semiconductor material, a conductive material, or the like.

Subsequently, the sacrificial layers formed in the contact holes CTH may be removed, and insulating spacers 103 may be formed by etching the insulating layers. Subsequently, contact plugs 106 may be formed in the contact holes CTH.

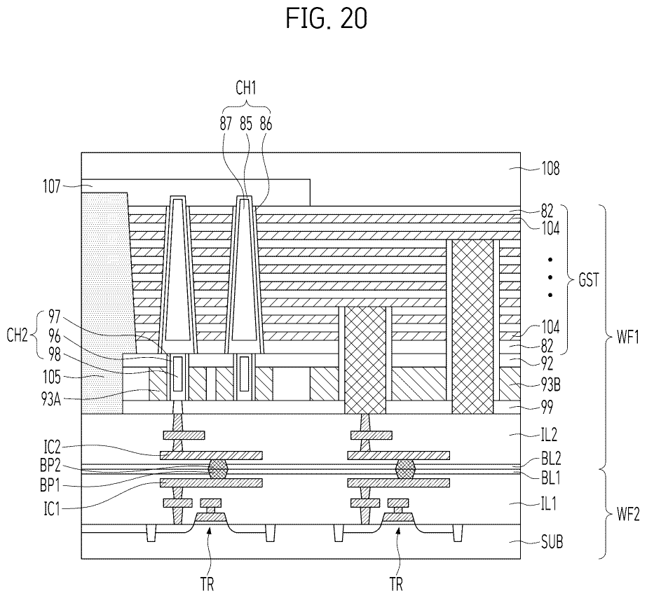

Referring to FIG. 20, a second interconnection structure IC2, a second interlayer insulating layer IL2, a second bonding layer BL2, and a second bonding pad BP2 may be formed on the insulating layer 99. Through this, a first wafer WF1 including the gate structure GST, the first channel structure CH1, the second channel structure CH2, the gate lines 93A, the dummy gate line 93B, and the contact plugs 106 may be formed.

A second wafer WF2 including a peripheral circuit may be formed separately from a process of forming the first wafer WF1. As an example, transistors TR may be formed on a substrate SUB, and a first interconnection structure IC1, a first interlayer insulating layer IL1, a first bonding layer BL1, and a first bonding pad BP1 may be formed.

Subsequently, the first wafer WF1 and the second wafer WF2 may be bonded to each other, and a rear surface of the gate structure GST may be exposed by removing a substrate 80. Subsequently, the first channel layer 85 may be exposed by removing the memory layer 86, and a source structure 107 may be formed on the gate structure GST. Subsequently, an insulating layer 108 may be formed on the source structure 107.

In accordance with the method described above, the gate lines 93A and the dummy gate line 93B may be formed over the stack ST. The dummy gate line 93B may be formed when the gate lines 93A are formed, and the preliminary contact holes PCTH may be formed when the second channel holes CHH2 are formed. When the contact holes CTH are formed by extending the preliminary contact holes PCTH, the dummy gate line 93B may be used as the hard mask. Accordingly, a process of the cell region CR and a process of the contact region CTR may be merged with each other, and a manufacturing cost of the semiconductor device may be reduced.

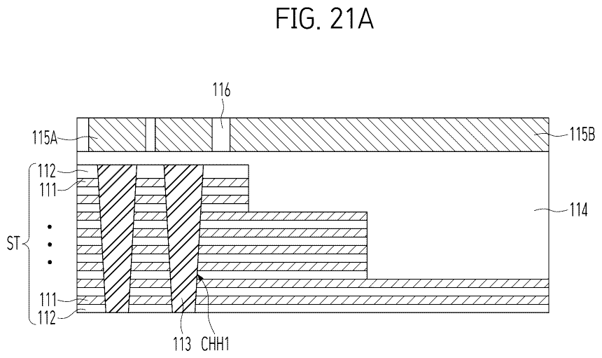

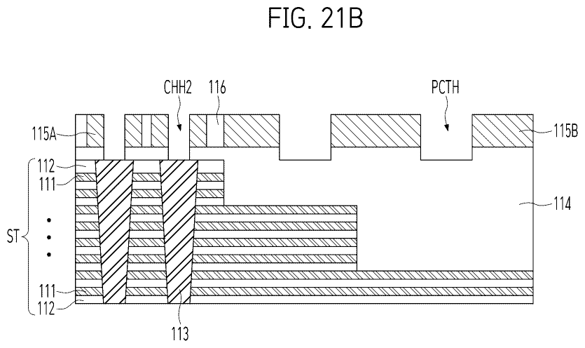

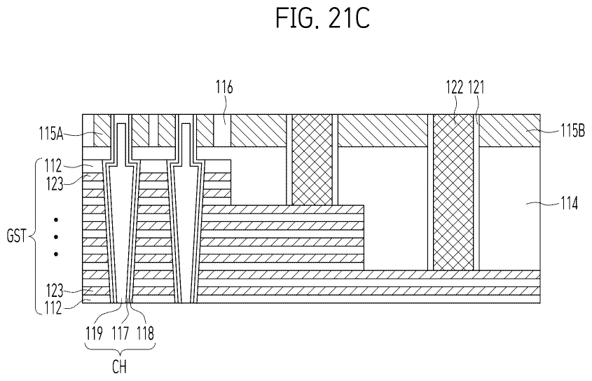

FIGS. 21A to 21C are diagrams for describing a method of manufacturing a semiconductor device in accordance with an embodiment of the present disclosure. Hereinafter, content overlapping with previously described content may be omitted.

Referring to FIG. 21A, a stack ST including first material layers 111 and second material layers 112, which are alternately stacked, may be formed. Subsequently, a first channel hole CHH1 penetrating through the stack ST may be formed. Subsequently, a sacrificial layer 113 may be formed in the first channel hole CHH1. The sacrificial layer 113 may include a material having a high etching selectivity with respect to the first material layers 111 and the second material layers 112. As an example, the sacrificial layer 113 may include a polysilicon layer or a carbon layer.

Subsequently, the stack ST may be patterned in a staircase shape. As an example, a staircase structure may be formed by etching the stack ST so that each of the first material layers 111 is exposed. Subsequently, an insulating layer 114 may be formed on the stack ST. Subsequently, the first material layers 111 may be replaced with third material layers 123. The third material layers 123 may each include metal such as tungsten (W) or molybdenum (Mo). Through this, a gate structure GST including the second material layers 112 and the third material layers 123, which are alternately stacked, may be formed. For reference, it is also possible to omit a process of replacing the first material layers 111 with the third material layers 123 and use the stack ST as the gate structure GST.

Subsequently, a conductive layer may be formed over the gate structure GST, and gate lines 115A and a dummy gate line 115B may be formed by patterning the conductive layer. Subsequently, an insulating material may be formed between the gate lines 115A and the dummy gate line 115B, and an insulating layer 116 may be formed by planarizing the insulating material until the gate lines 115A and the dummy gate line 115B are exposed. The gate line 115A and the dummy gate line 115B are used as stop layers when the insulating material is planarized, thus the disclosed embodiments provide a capability to reduce the occurrence of dishing even though a step form due to the staircase structure exists.

Referring to FIG. 21B, a second channel hole CHH2 penetrating through the gate line 115A and exposing the sacrificial layer 113 may be formed. Preliminary contact holes PCTH penetrating through the dummy gate line 115B and exposing the insulating layer 114 may be formed. When the second channel hole CHH2 is formed, the preliminary contact holes PCTH may be formed. The preliminary contact holes PCTH may each have a greater width than the second channel hole CHH2.

Referring to FIG. 21C, sacrificial layers may be formed in the second channel hole CHH2 and the preliminary contact holes PCTH. Subsequently, the sacrificial layer formed in the second channel hole CHH2 may be removed, and the first channel hole CHH1 may be reopened by removing the sacrificial layer 113 through the second channel hole CHH2. Subsequently, a channel structure CH may be formed in the first and second channel holes CHH1 and CHH2. The channel structure CH may include a channel layer 117, a memory layer 118, and an insulating core 119. Subsequently, the sacrificial layers formed in the preliminary contact holes PCTH may be removed.

Subsequently, the preliminary contact holes PCTH may extend (or be penetrated) into the insulating layer 114 so as to expose the first material layers 111, respectively. Through this, contact holes CTH having different depths may be formed. When the contact holes CTH are formed, the dummy gate line 115B may be used as a hard mask. Subsequently, insulating spacers 121 and contact plugs 122 may be formed in the contact holes CTH.

In accordance with the method described above, the gate lines 115A and the dummy gate line 115B may be formed over the gate structure GST including the staircase structure. The dummy gate line 115B may be formed when the gate lines 115A are formed, and the preliminary contact holes PCTH may be formed when the second channel holes CHH2 are formed. When the contact holes CTH are formed by extending the preliminary contact holes PCTH, the dummy gate line 115B may be used as the hard mask.

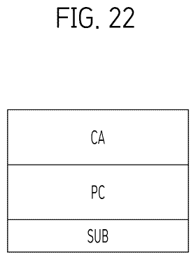

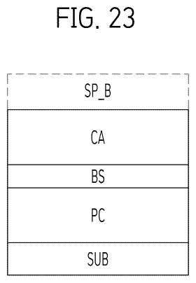

The structure and the manufacturing method according to the over-described embodiments may be applied to semiconductor devices of various structures. FIGS. 22 and 23 illustrate a schematic configuration of a semiconductor device to which the over-described embodiments are applicable.

FIG. 22 is a configuration diagram of a semiconductor device according to an embodiment of the present disclosure.

Referring to FIG. 22, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include gallium arsenide (GaAs), gallium nitride (GaN), gallium phosphide (GaP), gallium arsenide phosphide (GaAsP), gallium indium arsenide phosphide (GaInAsP), aluminum arsenide (AlAs), aluminum gallium (AlGa), indium phosphide (InP), indium antimonide (InSb), or indium gallium arsenide InGaAs. The group II-VI compound semiconductor may include zinc sulfide (ZnS), zinc oxide (ZnO), or cadmium sulfide (CdS).

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an N-type metal-oxide-semiconductor (NMOS) transistor, a P-type metal-oxide-semiconductor (PMOS) transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 23 is a configuration diagram of a semiconductor device according to an embodiment of the present disclosure.

Referring to FIG. 23, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described over with reference to FIG. 22.

According to an embodiment, the semiconductor device may have a structure in which the embodiments described over with reference to FIGS. 22 and 23 are combined or may have a partially modified structure. In the embodiment described with reference to FIGS. 22 and 23, positions of the memory cell array CA and the peripheral circuit PC may be changed. At least one memory cell array CA and/or at least one peripheral circuit PC may be additionally bonded to the embodiment described with reference to FIGS. 22 and 23. In an embodiment, a portion of the peripheral circuitry PC may be disposed in the memory cell array CA.

Although embodiments according to the technical idea of the present disclosure have been described over with reference to the accompanying drawings, this is only for explaining the embodiments according to the concept of the present disclosure, and the present disclosure is not limited to the over embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a gate structure including conductive layers and insulating layers, which are alternately stacked;
a gate line disposed over the gate structure;
a dummy gate line disposed over the gate structure;
a first channel structure disposed to penetrate through the gate structure;
a second channel structure disposed to penetrate through the gate line, and connected to the first channel structure; and
contact plugs disposed to penetrate through the dummy gate line and extend into the gate structure, and respectively connected to the conductive layers.

2. The semiconductor device of claim 1, wherein the gate line and the dummy gate line are disposed at substantially the same level.

3. The semiconductor device of claim 1, wherein each of the gate line and the dummy gate line includes polysilicon.

4. The semiconductor device of claim 1, wherein the first channel structure comprises:
a first channel layer;
a memory layer disposed to surround the first channel layer; and
a first insulating core disposed in the first channel layer.

5. The semiconductor device of claim 1, wherein the second channel structure comprises:
a second channel layer connected to the first channel layer;
a gate insulating layer disposed to surround the second channel layer; and
a second insulating core disposed in the second channel layer.

6. The semiconductor device of claim 1,
wherein the gate line is disposed to extend in a first direction, and
wherein, in a second direction intersecting the first direction, a width of the dummy gate line is greater than a width of the gate line.

7. The semiconductor device of claim 1,
wherein the gate line is a drain select line, and
wherein the conductive layers include at least one source select line and word lines stacked over the at least one source select line.

8. The semiconductor device of claim 1, further comprising a peripheral circuit disposed under the gate structure.

9. The semiconductor device of claim 8, further comprising a bonding structure disposed between the peripheral circuit and the gate structure.

10. A semiconductor device comprising:
a gate structure including stacked word lines;
drain select lines disposed over the gate structure, and disposed to extend in a first direction;
a dummy drain select line disposed over the gate structure;
channel structures disposed to penetrate through the drain select lines, and disposed to extend into the gate structure; and
contact plugs disposed to penetrate through the dummy drain select line, and respectively connected to the word lines.

11. The semiconductor device of claim 10, wherein each of the channel structures comprises:
a first channel layer disposed to penetrate through the gate structure; and
a second channel layer disposed to penetrate through the drain select line, and connected to the first channel layer.

12. The semiconductor device of claim 10, further comprising a pair of slit structures disposed to extend in the first direction,
wherein the gate structure is disposed between the pair of slit structures.

13. The semiconductor device of claim 12, wherein the drain select lines and the dummy drain select line are disposed between the pair of slit structures.

14. The semiconductor device of claim 10, wherein, in a second direction intersecting the first direction, the dummy drain select line has a greater width than a width of each of the drain select lines.

15. The semiconductor device of claim 10, wherein the drain select lines and the dummy drain select line are disposed at a same level.

16. The semiconductor device of claim 10, wherein each of the drain select lines and the dummy drain select line includes polysilicon.

17. The semiconductor device of claim 10, further comprising a peripheral circuit disposed under the gate structure.

18. The semiconductor device of claim 17, further comprising a bonding structure disposed between the peripheral circuit and the gate structure.

19. A method of manufacturing a semiconductor device, the method comprising:
forming a stack including first material layers and second material layers, which are alternately stacked;
forming a first channel structure penetrating through the stack;
forming a gate line over the stack;
forming a dummy gate line over the stack;
forming a channel hole penetrating through the gate line to expose the first channel structure;
forming preliminary contact holes penetrating through the dummy gate line;
forming a second channel structure in the channel hole to be connected to the first channel structure;
extending the preliminary contact holes into the stack to respectively expose the first material layers to form contact holes; and
forming contact plugs in the contact holes.

20. The method of claim 19, further comprising forming a polysilicon layer on the stack,
wherein the gate line and the dummy gate line are formed by patterning the polysilicon layer.

21. The method of claim 19, wherein the preliminary contact holes are formed when the channel hole is formed.

22. The method of claim 19, wherein the forming of the second channel structure comprises:
forming sacrificial layers in the channel hole and the preliminary contact holes;
replacing the sacrificial layer formed in the channel hole with the second channel structure; and
removing the sacrificial layers formed in the preliminary contact holes.

23. The method of claim 19, further comprising:
forming insulating layers in the contact holes;
forming sacrificial layers in the contact holes;
replacing the first material layers with third material layers;
removing the sacrificial layers; and
etching the insulating layers to form insulating spacers.

24. A method of manufacturing a semiconductor device, the method comprising:
forming a stack including first material layers and second material layers, which are alternately stacked;
forming a first channel hole penetrating through the stack;
forming a conductive layer on the stack;
patterning the conductive layer to form a drain select line and a dummy drain select line;
forming a second channel hole penetrating through the drain select line to be connected to the first channel hole;
forming preliminary contact holes penetrating through the dummy drain select line;
extending the preliminary contact holes to respectively expose the first material layers to form contact holes; and
forming contact plugs in the contact holes.

25. The method of claim 24, further comprising:
forming a first channel layer in the first channel hole; and
forming a second channel layer in the second channel hole to be connected to the first channel layer.

26. The method of claim 24, further comprising patterning the stack to have a staircase shape.

27. The method of claim 24, wherein the extending of the preliminary contact holes comprises extending the preliminary contact holes into the stack.

28. The method of claim 27, further comprising:
forming insulating layers in the contact holes;
forming sacrificial layers in the contact holes;
replacing the first material layers with third material layers;
removing the sacrificial layers; and
etching the insulating layers to form insulating spacers.

29. The method of claim 28, wherein the third material layers comprise:
at least one source select line; and
word lines disposed over the at least one source select line.
